(19) United States
(12) Patent Application Publication
(10) Pub. No.: US 2009/0121309 A1
(43) Pub. Date: May 14, 2009

(54) SEMICONDUCTOR DEVICE AND METHOD FOR FABRICATING THE SAME

(75) Inventor: Seung Bum KIM, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/767,369

(22) Filed: Jun. 22, 2007

(30) Foreign Application Priority Data
Dec. 28, 2006 (KR) 10-2006-137005

(51) Int. Cl. H01L 21/76; H01L 21/467; H01L 29/06

(52) U.S. Cl. 257/506; 438/710; 438/400; 257/E21.486; 257/E21.54; 257/E29.02

(57) ABSTRACT

A method for fabricating a semiconductor device includes forming a device isolation structure on a semiconductor substrate to define an active region. A hard mask pattern defining a recess region is formed over the semiconductor substrate. The semiconductor substrate is selectively etched using the hard mask pattern to form a recess channel structure. The etching process for the semiconductor substrate is performed by two plasma etching methods under different etching conditions. The hard mask pattern is removed to expose the active region including the recess channel structure. A gate electrode is formed to fill the recess channel structure.

### CROSS-REFERENCES TO RELATED APPLICATIONS

The present application claims priority to Korean patent application number 10-2006-0137005, filed on Dec. 28, 2006, which is incorporated by reference in its entirety.

### BACKGROUND OF THE INVENTION

The present invention relates to a memory device. More particularly, the present invention relates to a semiconductor device having a recess field effect transistor (“FET”) and a method for fabricating the same.

As the need for integration of semiconductor devices has continuously increased to enhance the performance of semiconductor devices and to reduce manufacturing costs, techniques for stably reducing the size of semiconductor devices are necessary. The design rule of semiconductor devices is reduced to improve the speed and integration of the devices, thereby decreasing the channel length of a metal oxide semiconductor field effect transistor (“MOSFET”). However, the reduction of the channel length in a device shortens the gap between a source region and a drain region. This short channel effect (“SCE”) makes it difficult to effectively control the voltage of the drain region to affect the voltages of the source and channel regions, leading to the deterioration of characteristics of an active switching device. In addition, a planar MOSFET has a structural limitation in reducing the size of a device and has difficulty preventing the occurrence of SCE.

A recess FET is structured such that an active region at a lower portion of a gate region is recessed and a gate electrode is formed to fill the recessed region, thereby increasing the channel length. Such a structure enables a three-dimensional increase in the channel length which is decreased due to the reduction of design rule, resulting in reducing the area of the devices. With the high integration of a semiconductor device, the size of the device is reduced. Thus, the width of a recess channel structure is also reduced, thereby decreasing the radius of curvature of the lower portion of the channel. Therefore, an E-field is integrated and the thickness of a gate insulating film is decreased, making it difficult to control a threshold voltage. Accordingly, the characteristics of semiconductor devices deteriorate.

### BRIEF SUMMARY OF THE INVENTION

Embodiments of the present invention are directed to an improved recess transistor. According to one embodiment of the present invention, the improved recess transistor employs two plasma etching methods that are performed under different etching conditions.

According to an embodiment of the present invention, a method for fabricating a semiconductor device includes forming a device isolation structure in a semiconductor substrate. The device isolation structure defines an active region. A hard mask pattern is formed over the semiconductor substrate. The hard mask pattern defines a recess region. The semiconductor substrate is selectively etched using the hard mask pattern as an etching mask to form a recess channel structure. The etching process is performed using two plasma etching methods under different etching conditions. The hard mask pattern is removed to expose the semiconductor substrate including the recess channel structure. A gate electrode is formed to fill the recess channel structure.

According to another embodiment, a semiconductor device has a recess transistor that is fabricated according to the method for fabricating a semiconductor device described above.

### BRIEF DESCRIPTION OF THE DRAWINGS

FIG. 1 is a layout of a semiconductor device according to an embodiment of the present invention;

FIGS. 2a to 2g are cross-sectional views illustrating a method for fabricating a semiconductor device according to an embodiment of the present invention; and

FIGS. 3a to 3f are cross-sectional views illustrating a method for fabricating a semiconductor device according to an embodiment of the present invention.

### DESCRIPTION OF EMBODIMENTS

The present invention relates to an improved recess transistor. According to one embodiment of the present invention, the improved recess transistor includes a recess channel structure. The recess channel structure is formed by employing two plasma etching methods each performed under different etching conditions.

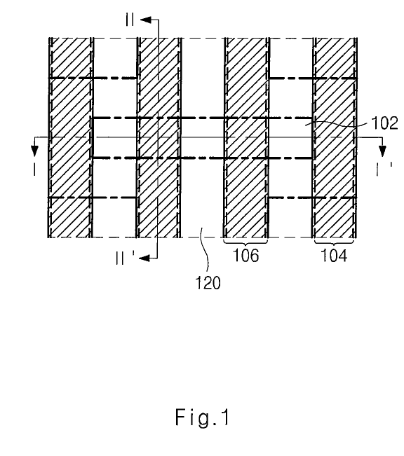

FIG. 1 is a layout of a semiconductor device according to an embodiment of the present invention. The semiconductor device includes an active region 102 defined by a device isolation region 120, a recess gate region 104 and a gate region 106. According to one embodiment of the present invention, the recess gate region 104 is disposed in the gate region 106. In addition, a line width of the recess gate region 104 is narrower than a line width of the gate region 106.

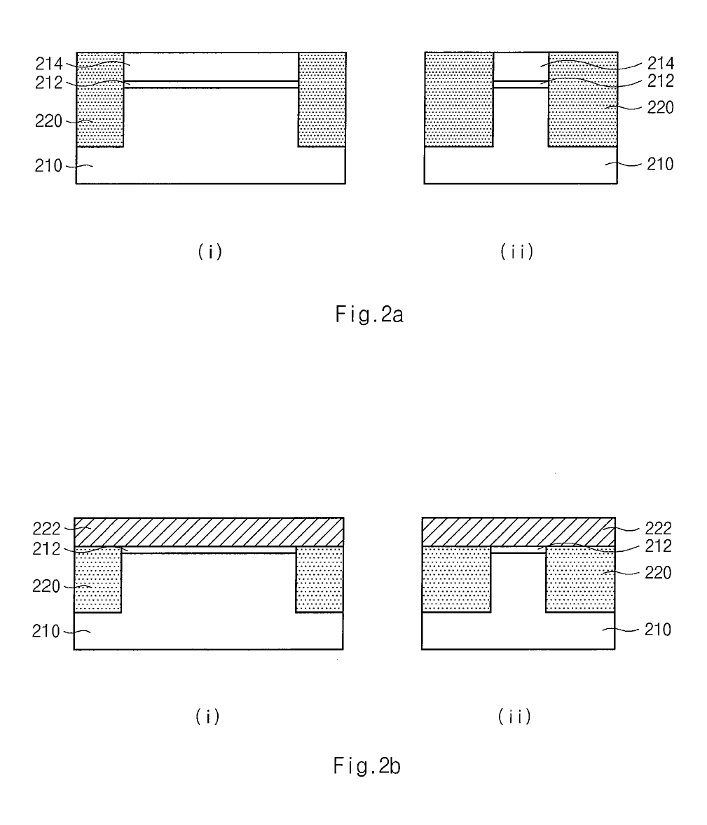

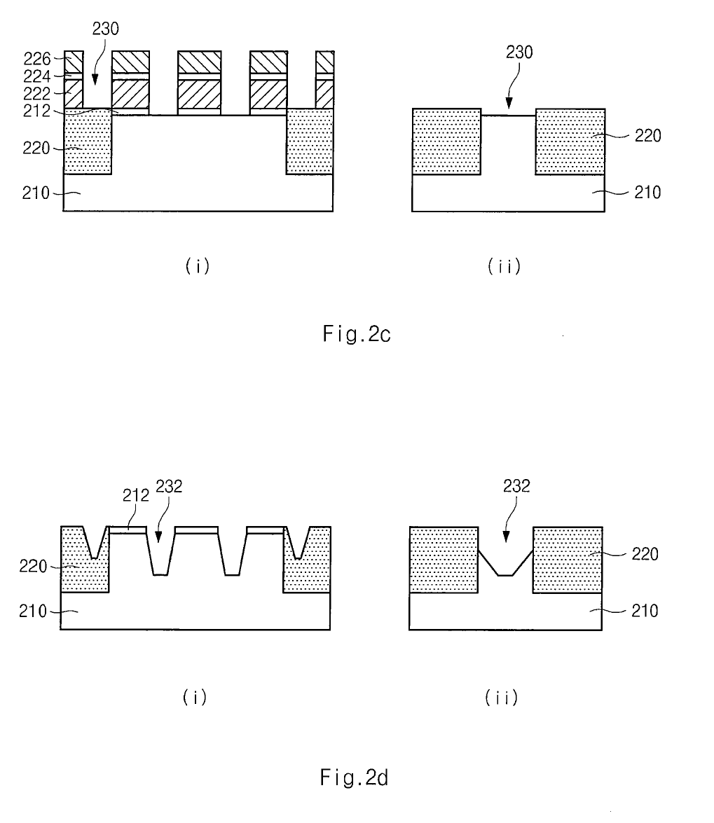

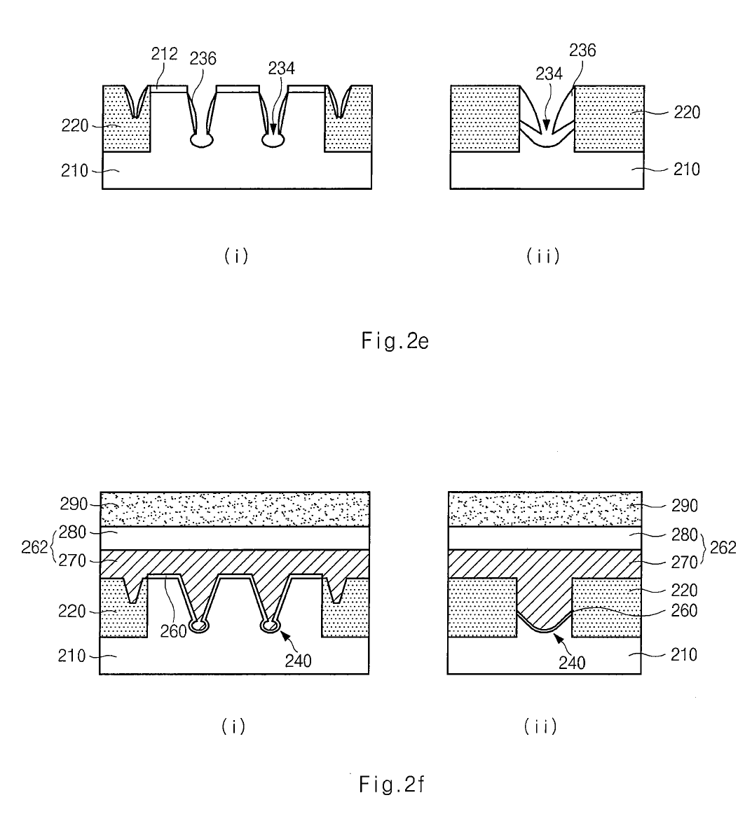

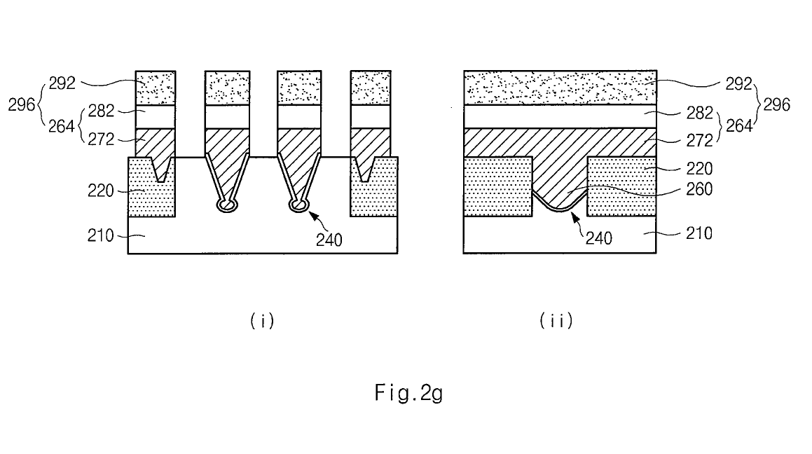

FIGS. 2a to 2g are cross-sectional views illustrating a semiconductor device according to the present invention. FIGS. 2a(i) to 2g(i) are cross-sectional views taken along the line I-I′ of FIG. 1, and FIGS. 2a(ii) to 2g(ii) are cross-sectional views taken along the line II-II′ of FIG. 1.

A pad oxide film 212 and a pad nitride film 214 are formed over a semiconductor substrate 210. The pad nitride film 214, the pad oxide film 212 and a thickness of the semiconductor device 210 are etched using a device isolation mask (not shown) as an etching mask to form a trench (not shown) that defines the active region 102 shown in FIG. 1. A device isolation film (not shown) is formed over the semiconductor substrate 210 to fill the trench. The device isolation film is polished until the pad nitride film 214 is exposed to form a device isolation structure 220. The pad nitride film 214 is removed to lower the height of the device isolation structure 220. A hard mask layer 222 is formed over the semiconductor substrate 210. Specifically, the hard mask layer 222 is formed over the pad oxide film 212 and the device isolation structure 220.

According to one embodiment of the present invention, the device isolation film is an oxide film. In addition, a stacked structure having a thermal oxide film (not shown), a liner nitride film (not shown) and a liner oxide film (not shown) is formed at the interface of the device isolation film and the trench. According to another embodiment of the present invention, the hard mask layer 222 is formed of a polysilicon layer, an amorphous carbon film, a nitride film, a silicon oxynitride layer or combinations thereof.

Referring to FIGS. 2c and 2d, a bottom anti-reflective coating (“BARC”) 224 is formed over the hard mask layer 222. A photoresist film (not shown) is formed over the BARC 224. The photoresist film is exposed and developed using a mask (not shown) corresponding to the recess gate region 104 shown in FIG. 1, to form a photoresist pattern 226. The BARC 224, the hard mask layer 222 and the pad oxide film 212 are etched using the photoresist pattern 226 as an etching mask to form a recess region 230 exposing the semiconductor substrate 210 at the bottom of the recess region 230. The exposed semiconductor substrate 210 and the device isolation structure 220 are etched to form a first recess 232. The photoresist pattern 226, the BARC 224 and the hard mask layer 222 are then removed.

According to one embodiment of the present invention, the BARC 224 is an organic bottom anti-reflective coating (“OBARC”). In addition, the etching process for forming the first recess 232 is performed by an anisotropic etching method.

Referring to FIGS. 2e to 2g, an insulating film (not shown) is formed over the top surface of the semiconductor substrate 210. The insulating film is selectively etched to form a spacer 236 on a sidewall of the pad oxide film 212 and the semiconductor substrate 210 in the first recess 232 shown in FIG. 2d. A thickness of the semiconductor substrate 210 exposed in the first recess 232 is etched using the spacer 236 as an etching mask to form a second recess 234. The second recess has a shape that is elliptical or circular.

A recess channel structure 240 includes the first recess 232 shown in FIG. 2d and the second recess 234. The pad oxide film 212 and the spacer 236 are removed to expose the semiconductor substrate 210 including the recess channel structure 240. A gate insulating film 260 is formed over the exposed semiconductor substrate 210. A gate conductive layer 262 is formed over the semiconductor substrate 210 to fill the recess channel structure 240. A gate hard mask layer 290 is formed over the gate conductive layer 262. The gate hard mask layer 290, the gate conductive layer 262 and the gate insulating film 260 are patterned using a gate mask (not shown) corresponding to the gate region 106 shown in FIG. 1, to form a gate structure 296 including a stacked structure of a gate hard mask pattern 292 and a gate electrode 264.

According to one embodiment of the present invention, the etching process for forming the second recess 234 is performed by an isotropic etching method to increase the radius of curvature of the lower portion of the recess channel structure 240. In addition, the gate conductive layer 262 is formed of a stacked structure including a lower gate conductive layer 270 and an upper gate conductive layer 280. In another embodiment, the gate electrode 264 includes an upper gate electrode 282 and a lower gate electrode 272.

The method for fabricating a semiconductor device according to one embodiment of the present invention as described below can effectively increase the radius of curvature of the lower portion of the recess channel structure compared to conventional methods. This method for fabricating a semiconductor device can also prevent the formation of a horn at the etched semiconductor substrate in the recess channel structure.

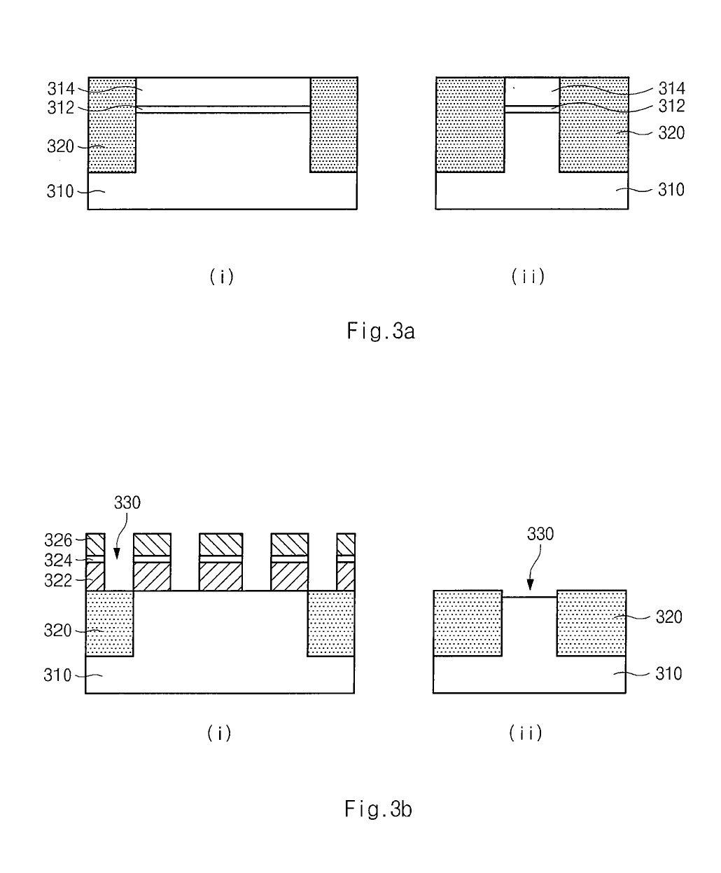

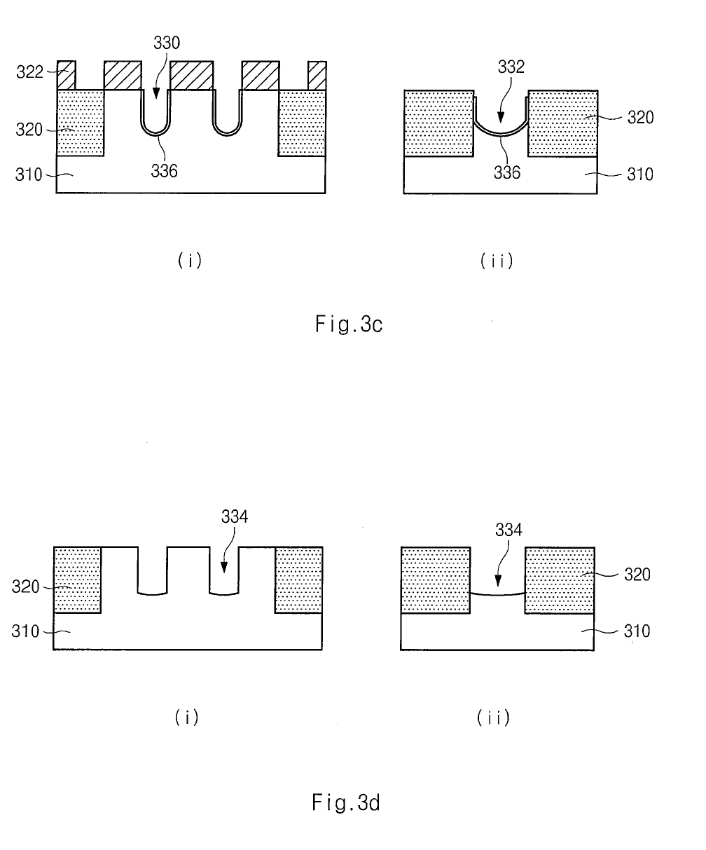

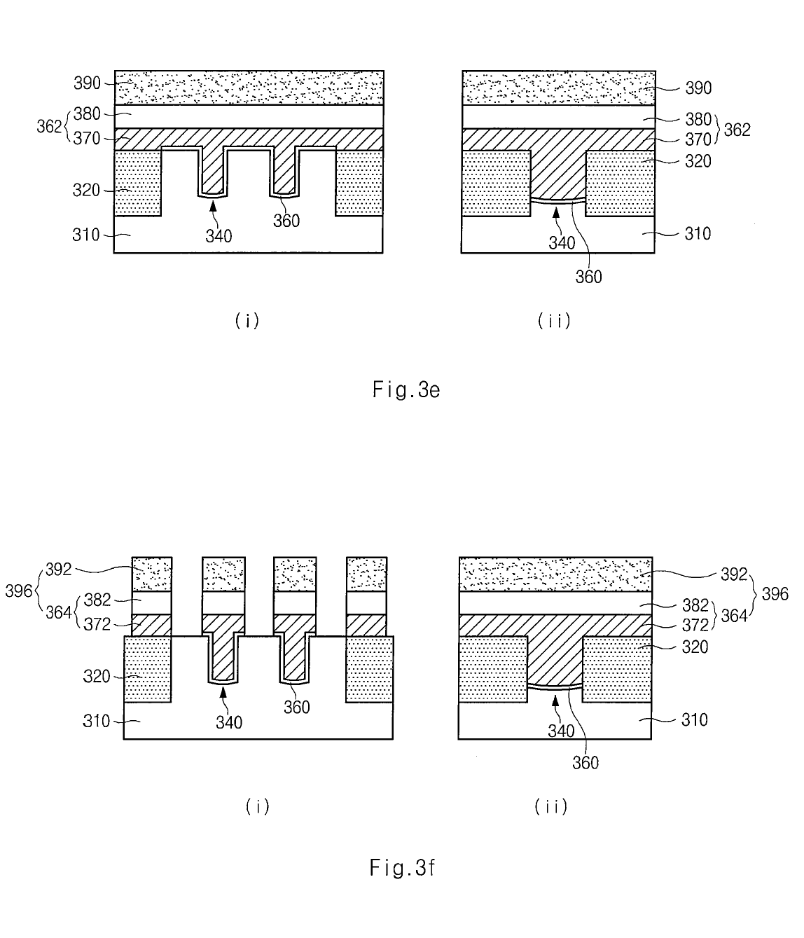

FIGS. 3a to 3f are cross-sectional views illustrating a method for fabricating a semiconductor device according to one embodiment of the present invention. FIGS. 3a(i) to FIGS. 3f(i) are cross-sectional views taken along the line I-I′ of FIG. 1, and FIGS. 3a(ii) to 3f(ii) are cross-sectional views taken along the line II-II′ of FIG. 1.

A pad oxide film 312 and a pad nitride film 314 are formed over a semiconductor substrate 310. The pad nitride film 314, the pad oxide film 312 and a thickness of the semiconductor substrate 310 are etched using a device isolation mask (not shown) to form a trench (not shown) to define the active region 102 shown in FIG. 1. A device isolation film (not shown) is formed over the semiconductor substrate 310 to fill the trench. The device isolation film is polished until the pad nitride film 314 is exposed to form a device isolation structure 320.

According to one embodiment of the present invention, the device isolation film is an oxide film. In addition, a stacked structure having a thermal oxide film (not shown), a liner nitride film (not shown) and a liner oxide film (not shown) is formed at the interface of the device isolation film and the trench.

Referring to FIG. 3b, the pad nitride film 314 and the pad oxide film 312 are removed to expose the semiconductor substrate 310. The height of the device isolation structure 320 is lowered. A hard mask layer (not shown) is formed over the semiconductor substrate 310. A bottom anti-reflective coating (“BARC”) is formed over the hard mask layer. A photoresist film (not shown) is formed over the BARC. The photoresist film is exposed and developed using a mask (not shown) corresponding to the recess gate region 104 shown in FIG. 1, to form a photoresist pattern 326. The BARC is etched using the photoresist pattern 326 as an etching mask to form a BARC pattern 324. The hard mask layer is etched using the BARC pattern 324 to form a hard mask pattern 322. A recess region 330 that exposes the semiconductor substrate 310 is defined by the hard mask pattern 322.

According to one embodiment of the present invention, the hard mask layer is formed of an oxide film, a nitride film or a combination thereof. In addition, the BARC is formed of an organic bottom anti-reflective coating. According to another embodiment of the present invention, the etching process for forming the BARC pattern 324 is performed by a plasma etching method using a gas such as CF₄, CHF₃, O₂ or combinations thereof. In addition, the etching process for forming the hard mask pattern 322 is performed by a plasma etching method using a gas such as CF₄, CHF₃, or a combination thereof.

Referring to FIG. 3c, the photoresist pattern 326 and the BARC pattern 324 are removed. The semiconductor substrate 310 exposed at the recess region 330 shown in FIG. 3b is etched using the hard mask pattern 322 as an etching mask. The exposed semiconductor substrate 310 is etched via a first anisotropic plasma etching method to form a first recess 332. A polymer protection layer 336 is formed on sidewalls of the first recess 332.

According to one embodiment of the present invention, the first plasma etching process uses a gas such as N₂, H₂, HBr, Cl₂, SiF₄ or combinations thereof. The first plasma etching process is performed under process conditions having a source power greater than approximately 300 W and a pressure less than approximately 20 mTorr. In another embodiment, the gas for the first plasma etching process is a mixture gas of HBr/Cl₂/N₂/H₂ or a mixture gas of HBr/Cl₂/N₂/SiF₄. In the first plasma etching process, the source power is in a range of approximately 300-2,000 W, a bias power is in a range of approximately 300-2,000 W, the pressure is in a range of approximately 2-20 mTorr, and a ratio of the source power to the bias power is in a range of approximately 1:1-3:1. In addition, a mixing ratio of HBr to Cl₂ is in a range of approximately 2:1-20:1, and a mixing ratio of the mixture gas of HBr and Cl₂ to N₂ is in a range of approximately 10:1-20:1.

According to another embodiment of the present invention, an amount of H₂ or SiF₄ is less than that of N₂. Accordingly, the polymer protection layer 336 is formed within the first recess 332 during the first plasma etching process under the above-described conditions. In addition, the ratio of the etch selectivity of the semiconductor substrate to the oxide film is larger than approximately 5:1. Accordingly, the device isolation structure 320 is not significantly etched during the formation process of the first recess 332.

Referring to FIG. 3d, a lower surface of the first recess 332 is etched by a second isotropic plasma etching method to form a second recess 334. The protection layer 336 and the hard mask pattern 332 are removed to expose the semiconductor substrate 310.

According to one embodiment of the present invention, the second plasma etching process uses a gas such as a F-radical gas, O₂, He or combinations thereof. In addition, the second plasma etching process is performed under a process condition having a source power greater than approximately 500 W and a pressure less than approximately 30 mTorr. In another embodiment, the F-radical gas is CF₄, SF₆ or CHF₃. In addition, the source power is in a range of approximately 500-2,000 W, a bias power is less than approximately 100 W and the pressure is in a range of approximately 2-30 mTorr. Therefore, under the above-described conditions, the lower portion of the second recess 334 is sufficiently spaced from an adjacent second recess 334. In addition, the second recess 334 has a profile with a large radius of curvature. Therefore, the second plasma etching process can prevent the formation of a horn generated in the semiconductor substrate 310 adjacent to the device isolation structure 320 (referring to FIG. 3d(ii)).

Referring to FIGS. 3e and 3f, a gate insulating film 360 is formed over the exposed semiconductor substrate 310. A gate conductive layer 362 is formed over a top surface of the semiconductor substrate 310 to fill the recess channel structure 340. A gate hard mask layer 390 is formed over the gate conductive layer 362. The gate hard mask layer 390, the gate conductive layer 362 and the gate insulating film 360 are patterned by a gate mask (not shown) corresponding to the gate region 106 shown in FIG. 1, to form a gate structure 396. The gate structure 396 includes a stacked structure of a gate hard mask pattern 392 and a gate electrode 364.

According to one embodiment of the present invention, the recess channel structure 340 includes the first recess 332 and the second recess 334. In addition, the gate conductive layer 362 is formed of a stacked structure having a lower gate conductive layer 370 and an upper gate conductive layer 380. In another embodiment, the gate electrode 364 includes an upper gate electrode 382 and a lower gate electrode 372.

As described above, the semiconductor device and the method for fabricating the same according to the present invention provide an improved recess transistor including a recess channel structure having a profile with a large radius of curvature. In addition, an etching horn is prevented from being formed in a semiconductor substrate adjacent to the device isolation structure during a second isotropic plasma etching process. Furthermore, the manufacturing process is simplified by eliminating a process for forming a spacer during the etching process for forming the second recess.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or a non-volatile memory device. Other additions, subtractions, or modifications are obvious in view of the present disclosure and are intended to fall within the scope of the appended claims.

1. A method for fabricating a semiconductor device, the method comprising:
forming a hard mask pattern over the semiconductor substrate, wherein the hard mask pattern defines a recess region;
selectively etching the semiconductor substrate using the hard mask pattern as an etch mask to form a recess channel structure at the recess region, wherein the semiconductor substrate is etched by two plasma etching methods under different etching conditions;
removing the hard mask pattern to expose the semiconductor substrate including the recess channel structure; and
forming a gate electrode to fill the recess channel structure.

2. The method of claim 1, wherein the hard mask pattern is formed of one film selected from the group consisting of: an oxide film, a nitride film and a combination thereof.

3. The method of claim 1, wherein etching the semiconductor substrate includes:
performing a first anisotropic plasma etching process on the semiconductor substrate exposed at the recess region using the hard mask pattern as an etching mask to form a first recess having a polymer buffer layer therein;
performing a second isotropic plasma etching process on the semiconductor substrate on a lower surface of the first recess to form a second recess having a large radius of curvature; and
removing the polymer buffer layer to form the recess channel structure.

4. The method of claim 3, wherein the first plasma etching process is performed using an etching gas selected from the group consisting of: HBr, Cl₂, N₂, H₂, SiF₄, and combinations thereof.

5. The method of claim 4, wherein the etching gas of the first plasma etching process is a mixture gas of HBr/Cl₂/N₂/H₂ or a mixture gas of HBr/Cl₂/N₂/SiF₄.

6. The method of claim 5, wherein in the mixture gas, a mixing ratio of HBr to Cl₂ is in a range of approximately 2:1-20:1.

7. The method of claim 5, wherein in the mixture gas, a mixing ratio of a mixture gas of HBr/Cl₂ to N₂ is in a range of approximately 10:1-20:1.

8. The method of claim 5, wherein in the mixture gas, an amount of H₂ is less than an amount of N₂.

9. The method of claim 3, wherein the first plasma etching process is performed under a process condition having a source power in a range of approximately 300-2,000 W, a bias power in a range of approximately 300-2,000 W, a ratio of the source power to the bias power in a range of approximately 1:1-3:1, and a pressure in a range of approximately 2-20 mTorr.

10. The method of claim 3, wherein the second plasma etching process is performed using an etching gas selected from the group consisting of: CF₄, SF₆, CHF₃, O₂, He and combinations thereof.

11. The method of claim 3, wherein the second plasma etching process is performed under a process condition having a source power in a range of approximately 500-2,000 W, a bias power less than approximately 100 W, and a pressure in a range of approximately 2-30 mTorr.

12. The method of claim 1, further comprising forming a device isolation structure in a semiconductor substrate, wherein the device isolation structure defines an active region.

13. A semiconductor device fabricated by the method according to claim 1.
